(19) United States
(12) Patent Application Publication
(10) Pub. No.: US 2019/0391187 A1
(43) Pub. Date: Dec. 26, 2019

(54) CIRCUIT AND METHOD FOR MONITORING A SUPPLY VOLTAGE

(71) Applicant: Robert Bosch GmbH, Stuttgart (DE)

(72) Inventors: Alexander Barner, Reutlingen (DE); Federico Ignacio Sanchez Pinzon, Kornwestheim (DE); Michael Wilhelm Haas, Stuttgart (DE); Uwe Lueders, Kusterdingen-Jettenburg (DE)

(21) Appl. No.: 16/480,066

(22) PCT Filed: Jan. 8, 2018
(86) PCT No.: PCT/EP2018/050313

§ 371 Date: Jul. 23, 2019

(30) Foreign Application Priority Data
Jan. 27, 2017 (DE) 10 2017 201 303.6

(51) Int. Cl. G01R 19/165; G01R 31/00; G05F 1/46

(52) U.S. Cl. CPC G01R 19/16538; G05F 1/46; G01R 31/007; G01R 19/16576

(57) ABSTRACT

A circuit for monitoring a supply voltage for an electronic device. The circuit includes a first reference voltage source, which generates a first reference voltage; a comparison device, which compares the first reference voltage with the supply voltage; a voltage regulator for regulating the supply voltage, the first reference voltage serving as a reference for the voltage regulator and the output voltage of the voltage regulator which supplies at least the comparison device a second reference voltage source, which generates a second reference voltage; and at least one comparator, which compares the output voltage of the voltage regulator with the second reference voltage.

### FIELD

The present invention relates to a circuit for monitoring a supply voltage for an electronic device, as well as a method for carrying out the monitoring with the aid of a circuit. The present invention further relates to a computer program, which carries out each step of the method when it runs on a computer, as well as a machine-readable memory medium, which stores the computer program. Finally, the present invention relates to an electronic control unit, which is configured to carry out the method according to the present invention.

### BACKGROUND INFORMATION

Electronic devices such as, for example, an electronic (engine) control unit are supplied with a supply voltage. In particular, in the case of CMOS (complementary metal-oxide semiconductor) logic often used today, at least the field effect transistors (MOSFET) are operated using a supply voltage of 5 volts referred to as “VDD5”. The supply voltage is monitored in order to guarantee the function of the electronic device.

The ISO 26262 is a standard of the International Organization for Standardization, which relates to safety-relevant electronic devices and systems in motor vehicles. The implementation of this standard is intended to ensure the functional safety of the electronic device and of its electronic/electrical components in the motor vehicle. In the ISO 26262, an ASIL classification (Automotive Safety Integrity Level) is used for the classification of functional safety. In this case, an error to be assumed as occurring is assessed by three factors, a first factor reflecting the severity of the error, a second factor reflecting the probability of occurrence and a third factor reflecting the controllability of the error, and the factors are then summed. The sum of the factors is then assigned in ascending order the designations ASIL A through ASIL D, ASIL D corresponding to the greatest error to be assumed.

The supply voltage influences all safety-critical functions of the electronic control unit in the motor vehicle. For this reason, it is desired that the monitoring of the supply voltage of the electronic control unit meets at least ASIL C, ideally, ASIL D.

The monitoring of the supply voltage is customarily carried out with the aid of a comparison device by directing the supply voltage past a voltage divider and subsequently comparing it with a first reference voltage using two comparators. Traditionally, the functionality of the voltage divider and of the two comparators may be tested by exchanging the input signals of the two comparators. A voltage regulator for regulating the supply voltage is also provided, for which the reference voltage also serves as its reference and whose output voltage supplies at least the comparison device. It is apparent that the first reference voltage in this comparison device is essential and must be precisely known.

### SUMMARY

In accordance with the present invention, an example monitoring of the supply voltage for an electronic device is provided, which according to the ISO 26262 meets an ASIL classification (Automotive Safety Integrity Level) of at least ASIL C, ideally of ASIL D.

A circuit for monitoring the supply voltage is provided, which includes a first reference voltage source, a comparison device and a voltage regulator. The first reference voltage source generates a first reference voltage. This first reference voltage is compared with the supply voltage using the comparison device, in order in this way to identify deviations of the supply voltage. The reference voltage also serves the voltage regulator as its reference. The voltage regulator regulates the supply voltage, the output voltage of the voltage regulator supplying at least the comparison device.

The circuit also includes a second reference voltage source which, in turn, generates a second reference voltage, and at least one comparator, which compares the output voltage of the voltage regulator with the second reference voltage. As a result of this circuit, the voltage regulator is monitored directly with the aid of its output voltage on the one hand. On the other hand, the first reference voltage is also monitored in the course of the monitoring of the output voltage of the voltage regulator, since the first reference voltage serves as a reference for the voltage regulator and thus correlates with its output voltage. If a change of the first reference voltage occurs, for example, in the form of a drift, then the output voltage of the voltage regulator also changes which, in turn, is identified by the comparator.

The circuit for monitoring the supply voltage may be used, in particular, for a VDD5 supply voltage, which is 5 volts, and in electronic devices used today, which are based on a CMOS logic and which use field effect transistors (MOSFET), which are operated using this VDD5 supply voltage of 5 volts.

According to one aspect of the present invention, the comparator may be configured to output an error signal if the output voltage is above the second reference voltage. According to another aspect, the comparator may be configured to output an error signal if the output voltage is below the second reference value. A combination of these two comparators is preferably used in order to output the error signal if the output voltage deviates from the second reference voltage. An optimum monitoring of the output voltage of the voltage regulator and, together with this, an optimum monitoring of the voltage regulator itself, as well as of the first reference voltage, is achieved as a result.

The comparison device is advantageously designed as an application-specific integrated circuit (ASIC) and includes, in particular, a voltage divider and two comparators, which compare the supply voltage with the first reference voltage. As a result of this, it is possible to precisely identify a deviation of the supply voltage from the first reference voltage.

The second reference voltage source and the comparator described above are preferably also part of the comparison device. This yields the advantage that an implementation of the electronic device is simplified, since the entire circuit may be modularly connected. The advantage presented is even greater if the comparison device is designed in the form of the ASIC.

In order to check the second reference voltage, the second reference voltage source may include a test circuit, in particular, an integrated test circuit for a built-in self-test. If it is established via the test circuit that the second reference voltage is incorrect, a corresponding error response may then be triggered.

An example method is also provided for monitoring the supply voltage for the electronic device with the aid of the previously described circuit. In this method, the supply voltage is initially compared with the first reference voltage. If the supply voltage is above or below the first reference voltage, thus, the supply voltage deviates from the first reference voltage, then a first or a second error signal is output. Furthermore, the output voltage of the voltage regulator is compared with the second reference voltage. A third error signal is subsequently output on the basis of the comparison of the output voltage of the voltage regulator with the second reference voltage.

According to one aspect, the third error signal is output if the output voltage of the voltage regulator is above the second reference voltage, and according to another aspect, the third error signal is output if the output voltage of the voltage regulator is below the second reference voltage. As a result, the third error signal may be output if the output voltage of the voltage regulator deviates from the second reference voltage.

The error source may be deduced from the third error signal, in this case, the first reference voltage (reference voltage source) and the voltage regulator specifically being included as potential error sources. An erroneous first reference voltage may, in particular, be deduced, if at the same time the supply voltage deviates from the first reference voltage and the output voltage of the voltage regulator deviates from the second reference voltage.

The computer program is configured to carry out each step of the method, in particular, when it is carried out on a computer or in a control unit. It enables the implementation of the method in a conventional electronic control unit, without structural changes having to be made to the control unit. For this purpose, it is stored on the machine-readable memory medium.

By uploading the computer program to a conventional electronic control unit, the electronic control unit that is configured to monitor the supply voltage is obtained.

### BRIEF DESCRIPTION OF THE DRAWINGS

Exemplary embodiments of the present invention are depicted in the figures and described in greater detail below.

FIG. 1 shows a circuit diagram of one exemplary embodiment of the circuit according to the present invention.

### DETAILED DESCRIPTION OF EXAMPLE EMBODIMENTS

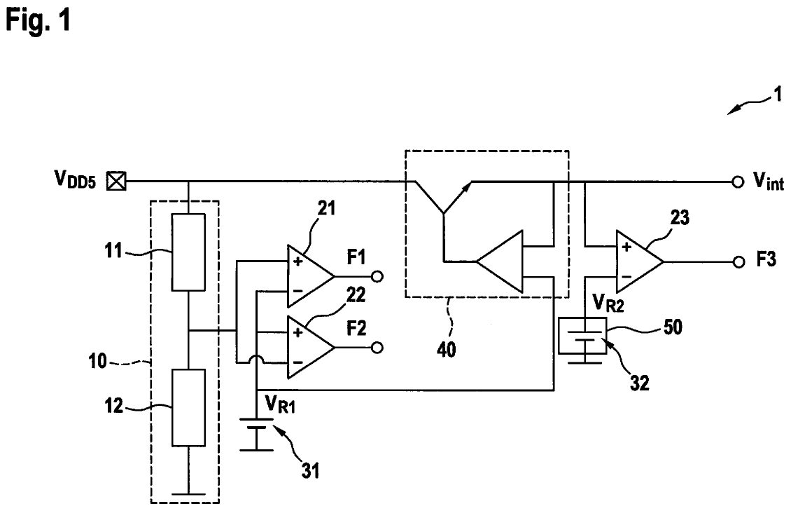

The circuit according to the present invention is depicted in one exemplary embodiment as a circuit diagram in FIG. 1. An electronic device not depicted is operated using a supply voltage V_{DD5}. If the electronic device uses CMOS logic with field effect transistors, which is used, for example, in an electronic control unit for a motor vehicle, supply voltage V_{DD5} should be 5 volts. A comparison device 1 is used for monitoring supply voltage V_{DD5} and is designed as an application-specific integrated circuit (ASIC). Supply voltage V_{DD5} is applied via a voltage divider 10, which is constructed of two resistors 11 and 12. The resultant partial voltage in this case is compared with a first reference voltage V_{R1} generated by a first reference voltage source 31 with the aid of two comparators 21 and 22. The two comparators 21 and 22 and a third comparator 23 described below are, as depicted, each implemented, for example, as operation amplifiers and supply an output signal if the voltage at the non-inverted input—identified by “+” in FIG. 1—is above the voltage at the inverted input—identified by “−” in FIG. 1. In terms of first comparator 21, supply voltage V_{DD5} is connected to its non-inverted input “+” and first reference voltage V_{R1} is connected to its inverted input “−”. First comparator 21 outputs a first error signal F1 if supply voltage V_{DD5} is above first reference voltage V_{R1}. In terms of second comparator 22, supply voltage V_{DD5} is connected to its inverted input “−” and first reference voltage V_{R1} is connected to its non-inverted input “+”, in contrast to first comparator 21. Second comparator 22 outputs a second error signal F2 if supply voltage V_{DD5} is below first reference voltage V_{R1}. With such a circuit, it is possible to identify a deviation of supply voltage V_{DD5} from first reference voltage V_{R1}. Assuming that first reference voltage V_{R1} is error-free, an excessively high supply voltage V_{DD5} is deduced from the appearance of first error signal F1 and an excessively low supply voltage V_{DD5} is deduced from the appearance of second error signal F2.

A voltage regulator 40, which regulates voltage supply V_{DD5} and reduces potentially occurring fluctuations of the voltage supply, is also provided. Output voltage Vᵢₙₜ thereof supplies the ASIC, first reference voltage V_{R1} serving as a reference for the ASIC. As a result, a change of first reference voltage V_{R1}, for example, in the form of a drift, is expressed as a change of output voltage Vᵢₙₜ of voltage regulator 40.

According to the present invention, the circuit includes a third comparator 23 and a second reference source 32, both of which as ASIC are part of comparison device 1 in this exemplary embodiment. Third comparator 23 compares output voltage Vᵢₙₜ of voltage regulator 40 with a second reference voltage V_{R2} generated by second reference voltage source 32. Second reference voltage source 32 includes an integrated test circuit 50 for a built-in self-test, via which errors of second reference voltage V_{R2} are eliminated. In this exemplary embodiment of the circuit according to the present invention, the non-inverted input “+” of third comparator 23 is connected to output voltage Vᵢₙₜ of voltage regulator 40, and inverted input “−” of third comparator 23 is connected to reference voltage V_{R2}. If output voltage Vᵢₙₜ of voltage regulator 40 is above second reference voltage V_{R2}, a third error signal F3 is output and an error response may take place. In other exemplary embodiments, the inputs of third comparator 23 may be connected in reverse order. In still other exemplary embodiments, two or multiple third comparators may also be provided, whereby, for example, one of the third comparators according to the exemplary embodiment depicted in FIG. 1 and another of the third comparators may be connected in reverse order. Finally, a deviation of output voltage Vᵢₙₜ of voltage regulator 40 is deduced from the third error signal. The deviation of output voltage Vᵢₙₜ may take place, for example, due to a faulty voltage regulator 40. In this case, usually neither first error signal F1 nor second error signal F2 is output. On the other hand, a changed and therefore erroneous first reference voltage V_{R1}, as previously explained, may also result in the deviation of output voltage Vᵢₙₜ of voltage regulator 40. Erroneous first reference voltage V_{R1} results usually in the simultaneous appearance of first error signal F1 or of second error signal F2.

Consequently, the precise error source may be deduced during the monitoring of supply voltage V_{DD5} from a combined consideration of first error signal F1 and of second error signal F2, together with third error signal F3.

1-15 (canceled)

16. A circuit for monitoring a supply voltage for an electronic device, comprising:
a first reference voltage source configured to generate a first reference voltage;
a comparison device configured to compare the first reference voltage with the supply voltage;
a voltage regulator configured to regulate the supply voltage, the first reference voltage serving as a reference for the voltage regulator and the output voltage of which supplies at least the comparison device;
a second reference voltage source configured to generate a second reference voltage; and
at least one comparator configured to compares the output voltage of the voltage regulator with the second reference voltage.

17. The circuit as recited in claim 16, wherein the supply voltage is a VDD5 supply voltage.

18. The circuit as recited in claim 16, wherein the comparator is configured to output an error signal when the output voltage is above the second reference voltage.

19. The circuit as recited in claim 16, wherein the comparator is configured to output an error signal when the output voltage is below the second reference voltage.

20. The circuit as recited in claim 16, wherein the comparison device is an application-specific integrated circuit.

21. The circuit as recited in claim 16, wherein the comparison device includes two comparators, which compare the supply voltage with the first reference voltage, whether it is higher or lower than the first reference voltage.

22. The circuit as recited in claim 16, wherein the second reference voltage source and the comparator are part of the comparison device.

23. The circuit as recited in claim 16, wherein the second reference voltage source includes a test circuit configured to check the second reference voltage.

24. The circuit as recited in claim 23, wherein the test circuit is an integrated test circuit for a built-in self-test.

25. A method for monitoring a supply voltage for an electronic device, the method comprising:
comparing the supply voltage with a first reference voltage;
outputting a first error signal or a second error signal when the supply voltage is above or below the first reference voltage;
comparing an output voltage of a voltage regulator with a second reference voltage; and
outputting a third error signal based on the comparison of the output voltage of the voltage regulator with the second reference voltage.

26. The method as recited in claim 25, wherein the third error signal is output when the output voltage of the voltage regulator is above the second reference voltage.

27. The method as recited in claim 25, wherein the third error signal is output when the output voltage of the voltage regulator is below the second reference voltage.

28. A non-transitory machine-readable memory medium on which is stored a computer program for monitoring a supply voltage for an electronic device, the computer program, when executed by a computer, causing the computer to perform:
comparing the supply voltage with a first reference voltage;
outputting a first error signal or a second error signal when the supply voltage is above or below the first reference voltage;
comparing an output voltage of a voltage regulator with a second reference voltage; and
outputting a third error signal based on the comparison of the output voltage of the voltage regulator with the second reference voltage.

29. An electronic control unit configured to carry out a monitoring of a supply voltage for an electronic device, the electronic control unit configured to:
compare the supply voltage with a first reference voltage;
output a first error signal or a second error signal when the supply voltage is above or below the first reference voltage;
compare an output voltage of a voltage regulator with a second reference voltage; and
output a third error signal based on the comparison of the output voltage of the voltage regulator with the second reference voltage.
